(19) United States
(12) Patent Application Publication
(10) Pub. No.: US 2024/0130049 A1
(43) Pub. Date: Apr. 18, 2024

(54) BENDING APPARATUS AND BENDING METHOD USING THE SAME

(71) Applicant: Samsung Display Co., LTD., Yongin-si (KR)

(72) Inventors: DONGWOO KIM, Yongin-si (KR); GEUMCHEOL KIM, Yongin-si (KR); MYUNGGIL CHOI, Yongin-si (KR)

(21) Appl. No.: 18/235,001

(22) Filed: Aug. 17, 2023

(30) Foreign Application Priority Data
Oct. 18, 2022 (KR) 10-2022-0134215

(51) Int. Cl. H05K 3/32

(52) U.S. Cl. CPC H05K 3/326; H05K 2203/02; H05K 2203/17

(57) ABSTRACT

A bending apparatus includes a first height control part which ascends in a first direction and descends in a direction opposite to the first direction, a second height control part spaced apart from the first height control part in a second direction crossing the first direction, and which ascends in the first direction and descends in the direction opposite to the first direction, a first rotation part attached to the first height control part, and which rotates with respect to a rotation axis, a second rotation part attached to the second height control part, and which rotates with respect to the rotation axis, and a supporting part disposed between the first and second rotation parts, where a first end of the supporting part is attached to the first rotation part, and a second end of the supporting part is attached to the second rotation part.

This application claims priority to Korean Patent Application No. 10-2022-0134215, filed on Oct. 18, 2022, and all the benefits accruing therefrom under 35 U.S.C. § 119, the content of which in its entirety is herein incorporated by reference.

### BACKGROUND

### 1. Field

The disclosure relates to a bending apparatus for manufacturing a display device and a bending method using the bending apparatus.

### 2. Description of the Related Art

Some components included in a display device may have flexibility, and such flexible components may be bent in a specific shape. To bend the display device, a bending method using a bending apparatus may be performed.

### SUMMARY

In a case where a bending method is performed using a bending apparatus, display quality of a display device manufactured thereby may deteriorated due to damage to the display device due to bending.

Embodiments provide a bending apparatus for preventing damage to a display device.

Embodiments provide a bending method using the bending apparatus.

A bending apparatus according to embodiments includes a first height control part which ascends in a first direction and descends in a direction opposite to the first direction, a second height control part spaced apart from the first height control part in a second direction crossing the first direction, where the second height control part ascends in the first direction and descends in the direction opposite to the first direction, a first rotation part attached to the first height control part, where the first rotation part rotates with respect to a rotation axis, a second rotation part attached to the second height control part, where the second rotation part rotates with respect to the rotation axis, and a supporting part disposed between the first rotation part and the second rotation part, where a first end of the supporting part is attached to the first rotation part, and a second end of the supporting part, which is opposite to the first end thereof, is attached to the second rotation part.

In an embodiment, the first height control part and the second height control part may be moveable independently of each other.

In an embodiment, when the first height control part relatively moves in the first direction or the direction opposite to the first direction with respect to the second height control part, the rotation axis may be inclined with respect to a plane defined by the second direction and a third direction crossing the first direction and the second direction.

In an embodiment, the first height control part may relatively move in a third direction crossing the first direction and the second direction and in a direction opposite to the third direction with respect to the second height control part.

In an embodiment, when the first height control part relatively moves in the third direction or the direction opposite to the third direction, the rotation axis may be inclined with respect to a plane defined by the first direction and the second direction.

In an embodiment, the supporting part may extend along an extending direction of the rotation axis, and rotate with respect to the rotation axis by the first rotation part and the second rotation part.

In an embodiment, the supporting part may include a fixing part, where a first end of the fixing part is attached to the first rotation part, and a second end of the fixing part, which is opposite to the first end thereof, is attached to the second rotation part, and a moving part which moves in a direction away from the fixing part and in a direction approaching the fixing part.

In an embodiment, the bending apparatus may further include a stage which relatively moves in a third direction crossing the first direction and the second direction and in a direction opposite to the third direction with respect to the supporting part.

In an embodiment, the stage may ascend in the first direction and descend in the direction opposite to the first direction.

In an embodiment, the first height control part may include a first lower frame and a first upper frame disposed on the first lower frame, where the first upper frame may ascend in the first direction and descend in the direction opposite to the first direction with respect to the first lower frame, and the second height control part may include a second lower frame and a second upper frame disposed on the second lower frame, where the second upper frame may ascend in the first direction and descend in the direction opposite to the first direction with respect to the second lower frame.

In an embodiment, the first rotation part may be attached to the first upper frame, and the second rotation part may be attached to the second upper frame.

In an embodiment, the first upper frame and the second upper frame may be moveable independently of each other.

A bending method according to embodiments includes preparing a bending apparatus including a first height control part configured to ascend in a first direction and to descend in a direction opposite to the first direction, a second height control part spaced apart from the first height control part in a second direction crossing the first direction, where the second height control part ascends in the first direction and descends in the direction opposite to the first direction, a first rotation part attached to the first height control part, where the first rotation part rotates with respect to a rotation axis, a second rotation part attached to the second height control part, where the second rotation part rotates with respect to the rotation axis, and a supporting part disposed between the first rotation part and the second rotation part, where a first end of the supporting part is attached to the first rotation part, and a second end of the supporting part, which is opposite to the first end thereof, is attached to the second rotation part, disposing a first portion of a bending target on the supporting part, and bending the bending target by rotating each of the first rotation part and the second rotation part with respect to the rotation axis.

In an embodiment, the bending the bending target may include relatively moving the first height control part in the first direction or in the direction opposite to the first direction with respect to the second height control part.

In an embodiment, the bending the bending target may include relatively moving the first height control part in a third direction crossing the first direction and the second direction or in a direction opposite to the third direction with respect to the second height control part.

In an embodiment, in the bending the bending target, the supporting part may rotate with respect to the rotation axis.

In an embodiment, the supporting part may include a fixing part including a first end attached to the first rotation part and a second end attached to the second rotation part, and a moving part which moves in a direction away from the fixing part or in a direction approaching the fixing part, and the bending the bending target may include relatively moving the moving part in the direction away from the fixing part or in the direction approaching the fixing part.

In an embodiment, the bending apparatus may further include a stage, and where the bending method may further include disposing a second portion of the bending target on the stage.

In an embodiment, the bending the bending target may include relatively moving the stage in a third direction crossing the first direction and the second direction or in a direction opposite to the third direction with respect to the supporting part.

In an embodiment, the bending the bending target may include moving the stage in the first direction or in the direction opposite to the first direction.

The bending apparatus according to embodiments may include a first height control part configured to ascend in a first direction and to descend in a direction opposite to the first direction, a second height control part spaced apart from the first height control part in a second direction crossing the first direction, and configured to ascend in the first direction and to descend in the direction opposite to the first direction, a first rotation part attached to the first height control part, and configured to rotate with respect to a rotation axis, a second rotation part attached to the second height control part, and configured to rotate with respect to the rotation axis, and a supporting part disposed between the first rotation part and the second rotation part, where a first end of the supporting part is attached to the first rotation part, and a second end opposite to the first end of the supporting part is attached to the second rotation part. In such an embodiment, inclination of the rotation axis of the first rotation part and the second rotation part may be adjusted or controlled by relative ascending or descending of the first height control part with respect to the second height control part. Accordingly, during a bending process, the bending target may be bent with respect to the rotation axis having an optimal inclination.

### BRIEF DESCRIPTION OF THE DRAWINGS

FIG. 1 is a block diagram illustrating a bending apparatus according to an embodiment.

FIG. 2, FIG. 3, FIG. 4, FIG. 5, and FIG. 6 are diagrams illustrating a bending part of the bending apparatus of FIG. 1.

FIG. 7 and FIG. 8 are diagrams illustrating a bending method according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device according to embodiments of the disclosure will be described in detail with reference to the accompanying drawings. The same or similar reference numerals are used for the same components in the accompanying drawings.

FIG. 1 is a block diagram illustrating a bending apparatus according to an embodiment.

Referring to FIG. 1, an embodiment of a bending apparatus 1000 may include a bending part 100 and a stage part 200. In an embodiment, the bending apparatus 1000 may be an apparatus for bending an element of a display device.

A bending target may be disposed on the bending part 100 and the stage part 200. In an embodiment, for example, a first portion of the bending target may be disposed on the bending part 100, and a second portion of the bending target may be disposed on the stage part 200.

The bending part 100 may rotate the first portion of the bending target based on a rotation axis. Accordingly, the bending target may be bent between the first portion of the bending target and the second portion of the bending target.

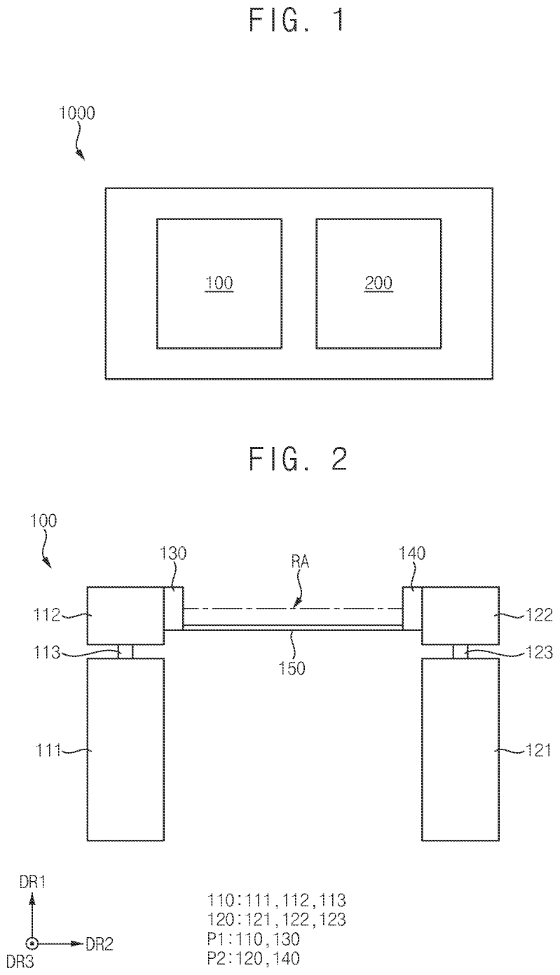

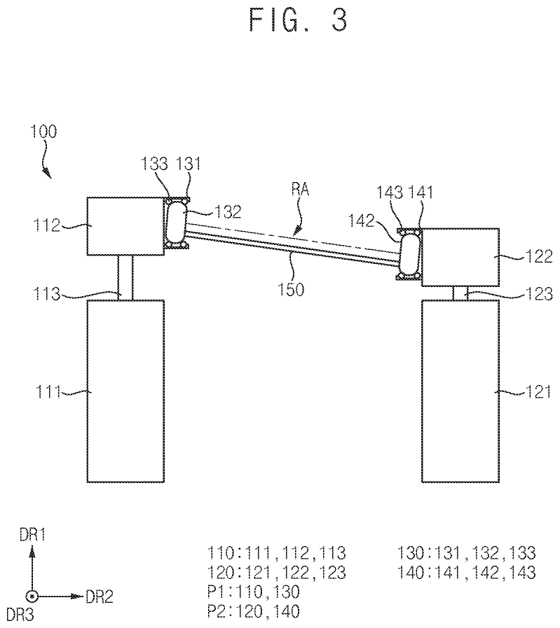

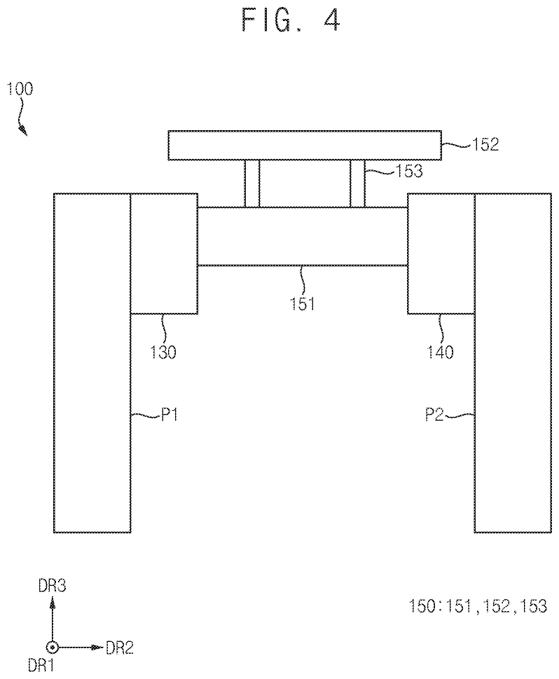

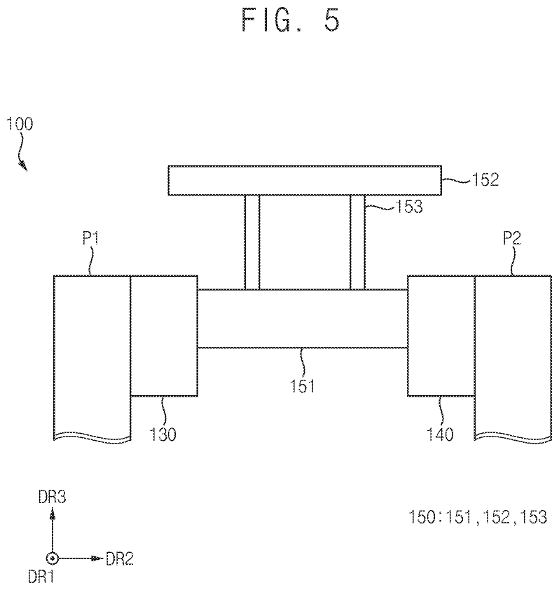

FIG. 2, FIG. 3, FIG. 4, FIG. 5, and FIG. 6 are diagrams illustrating a bending part of the bending apparatus of FIG. 1.

Referring to FIG. 2, an embodiment of the bending part 100 may include a first height control part 110, a second height control part 120, a first rotation part 130, a second rotation part 140, and a supporting part 150.

The first height control part 110 may be configured to ascend (e.g., allow at least a part thereof to ascend) in a first direction DR1 and descend (e.g., allow at least a part thereof to descend) in a direction opposite to the first direction DR1. In an embodiment, the first height control part 110 may include a first lower frame 111, a first upper frame 112 disposed on the first lower frame 111, and a first guide 113 disposed between the first lower frame 111 and the first upper frame 112. In such an embodiment, the first upper frame 112 may ascend in the first direction DR1 with respect to the first lower frame 111 by the first guide 113, or may descend in the direction opposite to the first direction DR1 with respect to the first lower frame 111 by the first guide 113.

The second height control part 120 may be spaced apart from the first height control part 110 in the second direction DR2 crossing the first direction DR1. The second height control part 120 may be configured to ascend in the first direction DR1 and descend in the direction opposite to the first direction DR1. In an embodiment, the second height control part 120 may include a second lower frame 121, a second upper frame 122 disposed on the second lower frame 121, and a second guide 123 disposed between the second lower frame 121 and the second upper frame 122. In such an embodiment, the second upper frame 122 may ascend in the first direction DR1 with respect to the second lower frame 121 by the second guide 123, or may descend in the direction opposite to the first direction DR1 with respect to the second lower frame 121 by the second guide 123.

In an embodiment, the first height control part 110 and the second height control part 120 may be movable independently of each other. In an embodiment, for example, the first guide 113 for ascending (or descending) the first upper frame 112 and the second guide 123 for ascending (or descending) the second upper frame 122 may be driven independently of each other, and accordingly, the first upper frame 112 and the second upper frame 122 may be movable independently of each other.

The first rotation part 130 may be attached to the first height control part 110. In an embodiment, for example, the first rotation part 130 may be attached to the first upper frame 112. In such an embodiment, since the first height control part 110 is configured to ascend in the first direction DR1 or descend in the direction opposite to the first direction DR1, the first rotation part 130 may also be configured to ascend in the first direction DR1 or descend in the direction opposite to the first direction DR1.

The second rotation part 140 may be attached to the second height control part 120. In an embodiment, for example, the second rotation part 140 may be attached to the second upper frame 122. In such an embodiment, since the second height control part 120 is configured to ascend in the first direction DR1 or descend in the direction opposite to the first direction DR1, the second rotation part 140 may also be configured to ascend in the first direction DR1 or descend in the direction opposite to the first direction DR1.

The supporting part 150 may be disposed between the first rotation part 130 and the second rotation part 140. In an embodiment, a first end of the supporting part 150 may be attached to the first rotation part 130, and a second end of the supporting part 150, which is opposite to the first end thereof, may be attached to the second rotation part 140. The supporting part 150 may extend along an extending direction of a rotation axis RA, and a first portion of the bending target may be disposed on the supporting part 150.

The first rotation part 130 and the second rotation part 140 may share the rotation axis RA. That is, each of the first rotation part 130 and the second rotation part 140 may rotate with respect to the rotation axis (or a same rotation axis) RA. In an embodiment, a rotation axis of the first rotation part 130 and a rotation axis of the second rotation part 140 are aligned with each other. In an embodiment, as shown in FIG. 2, when the first rotation part 130 and the second rotation part 140 are located at substantially a same level as each other (i.e., when the first upper frame 112 and the second upper frame 122 are located at substantially a same level as each other), the extension direction of the rotation axis RA may be the second direction DR2.

As each of the first rotation part 130 and the second rotation part 140 rotates with respect to the rotation axis RA, the supporting part 150 attached to the first rotation part 130 and the second rotation part 140 may also rotate with respect to the rotation axis RA. Accordingly, the first portion of the bending target disposed on the supporting part 150 may rotate with respect to the rotation axis RA, and the bending target may be bent.

Referring to FIG. 3, the first height control part 110 may relatively ascend in the first direction DR1 with respect to the second height control part 120. For example, a first distance between the first upper frame 112 and the first lower frame 111 may be larger than a second distance between the second upper frame 122 and the second lower frame 121.

Accordingly, the rotation axis RA may be inclined with respect to a plane defined by a third direction DR3 and the second direction DR2. The third direction DR3 may be a direction crossing the first direction DR1 and the second direction DR2. More specifically, as the first height control part 110 relatively ascends with respect to the second height control part 120, the first rotation part 130 may relatively ascend with respect to the second rotation part 140, and accordingly, the rotation axis RA may be inclined respect to the plane defined by a third direction DR3 and the second direction DR2.

In an embodiment, as described above, the supporting part 150 may be inclined with respect to the plane defined by the second direction DR2 and the third direction DR3. In such an embodiment, the supporting part 150 may rotate with respect to the rotation axis RA inclined with respect to the plane defined by the second direction DR2 and the third direction DR3.

In an embodiment, each of the first rotation part 130 and the second rotation part 140 may include a self-aligning bearing, air bearing, etc. to effectively prevent damage (for example, distortion, etc.) of the supporting part 150 due to inclination of the rotation axis RA.

In an embodiment, where each of the first rotation part 130 and the second rotation part 140 includes the self-aligning bearing, the first rotation part 130 may include an outer ring part 131, an inner ring part 132 and a connection part 133, and the second rotation part 140 may include an outer ring part 141, an inner ring part 142 and a connection part 143.

In an embodiment, the outer ring part 131 of the first rotation part 130 may be attached to the first upper frame 112. The inner ring part 132 of the first rotation part 130 may rotate with respect to the rotation axis RA in the outer ring part 131 of the first rotation part 130, and the first end of the supporting part 150 may be attached to the inner ring part 132 of the first rotation part 130. In such an embodiment, the inner ring part 132 of the first rotation part 130 may be inclined in response to the inclination of the rotation axis RA within the outer ring part 131 of the first rotation part 130. The connection part 133 of the first rotation part 130 may guide the inclination and rotational movement of the inner ring part 132 of the first rotation part 130 within the outer ring part 131 of the first rotation part 130. In an embodiment, the connection part 133 may include a ball or a roller.

In an embodiment, the outer ring part 141 of the second rotation part 140 may be attached to the second upper frame 122, and the inner ring part 142 of the second rotation part 140 may rotate with respect to the rotation axis RA in the outer ring part 141 of the second rotation part 140. In addition, the second end of the supporting part 150 may be attached to the inner ring part 142 of the second rotation part 140. In such an embodiment, the inner ring part 142 of the second rotation part 140 may be inclined in response to the inclination of the rotation axis RS within the outer ring part 141 of the second rotation part 140. The connection part 143 of the second rotation part 140 may guide the inclination and rotational movement of the inner ring part 142 of the second rotation part 140 within the outer ring part 141 of the second rotation part 140.

FIG. 3 shows an embodiment in which the first height control part 110 relatively ascends with respect to the second height control part 120, but the invention is not limited thereto. Alternatively, for example, the first height control part 110 may relatively descend with respect to the second height control part 120.

Referring to FIG. 4 and FIG. 5, each of FIG. 4 and FIG. 5 is a plan view illustrating the bending part 100 of FIG. 2 viewed from the first direction DR1.

In an embodiment, the supporting part 150 may include a fixing part 151, a moving part 152, and a guide 153.

A first end of the fixing part 151 may be attached to the first rotation part 130, and a second end of the fixing part 151, which is opposite to the first end thereof, may be attached to the second rotation part 140. Accordingly, the fixing part 151 may rotate by the rotation of the first rotation part 130 and the second rotation part 140.

The moving part 152 may be connected to the fixing part 151 by the guide 153. In an embodiment, the moving part 152 may move in a direction (for example, in the third direction DR3) away from the fixing part 151 by the guide 153, or in a direction (for example, in a direction opposite to the third direction DR3) approaching the fixing part 151 by the guide 153. In such an embodiment, the first portion of the bending target may be disposed on the moving part 152.

Referring to FIG. 6, the first height control part 110 may relatively move in the third direction DR3 with respect to the second height control part 120.

Accordingly, the rotation axis RA may be inclined with respect to a plane defined by the first direction DR1 and the second direction DR2. More specifically, as the first height control part 110 relatively moves in the third direction DR3 with respect to the second height control part 120, the first rotation part 130 may relatively move in the third direction DR3 with respect to the second rotation part 140, and accordingly, the rotation axis RA may be inclined with respect to a plane defined by the first direction DR1 and the second direction DR2.

In a case where the rotation axis RA is inclined with respect to a plane defined by the first direction DR1 and the second direction DR2, the supporting part 150 may be inclined with respect to the plane defined by the first direction DR1 and the second direction DR2. In addition, the supporting part 150 may rotate with respect to the rotation axis inclined with respect to the plane defined by the first direction DR1 and the second direction DR2.

In an embodiment, each of the first rotation part 130 and the second rotation part 140 may include a self-aligning bearing, air bearing, etc. to prevent damage (for example, distortion, etc.) of the supporting part 150 due to inclination of the rotation axis RA. In an embodiment, for example, as described with reference to FIG. 3, the first rotation part 130 may include the outer ring part 131, the inner ring part 132, and the connection part 133, and the second rotation part 140 may include the outer ring part 141, the inner ring part 142, and the connection part 143.

FIG. 6 shows an embodiment in which the first height control part 110 relatively moves in the third direction DR3 with respect to the second height control part 120, but the invention is not limited thereto. Alternatively, for example, the first height control part 110 may relatively move in the direction opposite to the third direction DR3 with respect to the second height control part 120.

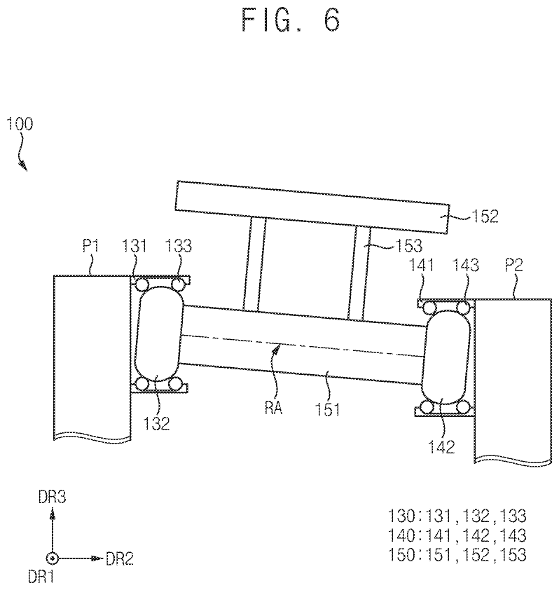

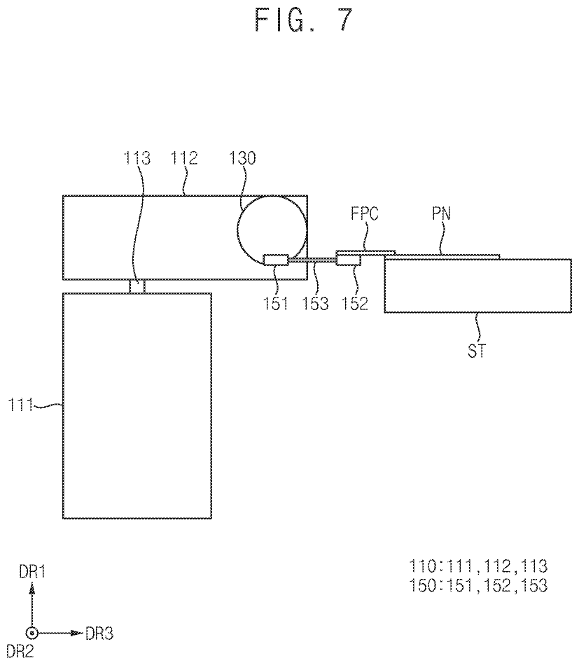

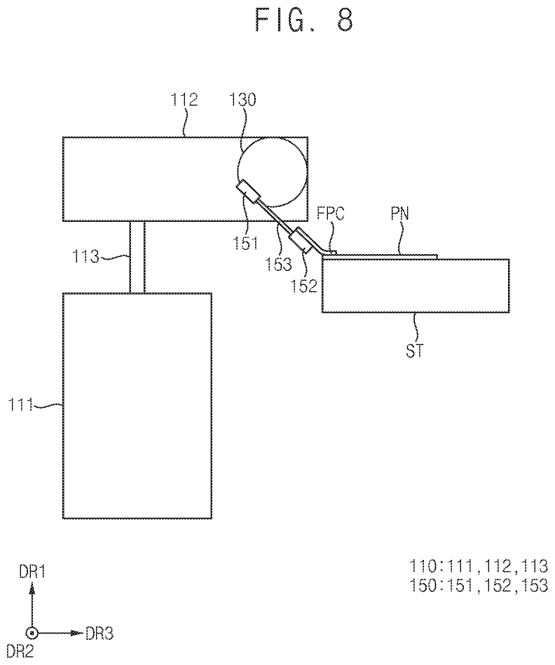

FIG. 7 and FIG. 8 are diagrams illustrating a bending method according to an embodiment. In FIG. 7 and FIG. 8, for convenience of illustration and description, the second height control part 120 and the second rotation part 140 are omitted.

An embodiment of a bending method may be a method of bending a bending target.

Referring to FIG. 7 and FIG. 8, the bending target may be disposed on the bending part 100 and the stage part 200.

The bending part 100 may include components described with reference to FIG. 2, FIG. 3, FIG. 4, FIG. 5, and FIG. 6. In an embodiment, for example, the bending part 100 may include the first height control part 110, the first rotation part 130, and the supporting part 150.

The stage part 200 may include a stage ST and a stage moving part (not shown). The stage moving part may move the stage in the first direction DR1, the second direction DR2, and/or the third direction DR3.

The bending target may include a display device. In an embodiment, the display device may include a display panel PN and a circuit substrate FPC. In such an embodiment, the display panel PN may be disposed on the stage ST, and a first portion of the circuit substrate FPC may be attached to the display panel PN, and a second portion of the circuit substrate FPC may be disposed on the supporting part 150.

In a bending method according to an embodiment, the bending target including the display panel PN and the circuit substrate FPC may be disposed on the moving part 152 and the stage ST.

Subsequently, each of the first rotation part 130 and the second rotation part 140 may rotate with respect to the rotation axis RA, and accordingly, the supporting part 150 fixed to each of the first rotation part 130 and the second rotation part 140 may rotate, and the bending target may be bent. In an embodiment, for example, the circuit substrate FPC of the bending target may be bent.

When bending the bending target, the first height control part 110 may relatively move with respect to the second height control part 120 in the first direction DR1 or in the direction opposite to the first direction DR1. That is, while the bending target is being bent, the rotation axis RX may be inclined in a real time with respect to the plane defined by the second direction DR2 and the third direction DR3.

When bending the bending target, the first height control part 110 may relatively move with respect to the second height control part 120 in the third direction DR3 or in the direction opposite to the third direction DR3. That is, while the bending target is being bent, the rotation axis RX may be inclined in a real time with respect to the plane defined by the first direction DR1 and the second direction DR2.

When bending the bending target, the moving part 152 may relatively move in the direction (for example, in the third direction DR3) away from the fixing part 151, or in the direction (for example, in the direction opposite to the third direction DR3) approaching the fixing part 151 in a real time. Accordingly, while the bending target is being bent, a distance between the first portion of the circuit substrate FPC attached to the display panel PN and the second portion of the circuit substrate FPC disposed on the moving part may increase or decrease.

When bending the bending target, the stage may move in the first direction DR1, the direction opposite to the first direction DR1, the third direction DR3, and/or the direction opposite to the third direction DR3.

In an embodiment, as described above, when bending the bending target, the rotation axis RX may be inclined, a position of the moving part 152 may be adjusted, or a position of the stage ST may be adjusted. In such an embodiment, when bending the bending target, at least one selected from inclining the rotation axis RX, adjusting the position of the moving part 152, and adjusting the position of the stage ST may be performed. In an embodiment, for example, when bending the bending target, the inclining of the rotation axis RX, the adjusting the position of the moving part 152, and the adjusting of the position of the stage ST may be simultaneously performed. Accordingly, an embodiment of the bending apparatus 1000 according to the invention may bend the bending target in an optimal bending path.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A bending apparatus comprising:
a first height control part which ascends in a first direction and descend in a direction opposite to the first direction;
a second height control part spaced apart from the first height control part in a second direction crossing the first direction, wherein the second height control part ascends in the first direction and descends in the direction opposite to the first direction;
a first rotation part attached to the first height control part, wherein the first rotation part rotates with respect to a rotation axis;
a second rotation part attached to the second height control part, wherein the second rotation part rotates with respect to the rotation axis; and
a supporting part disposed between the first rotation part and the second rotation part, wherein a first end of the supporting part is attached to the first rotation part, and a second end of the supporting part, which is opposite to the first end thereof, is attached to the second rotation part.

2. The bending apparatus of claim 1, wherein the first height control part and the second height control part are moveable independently of each other.

3. The bending apparatus of claim 1, wherein when the first height control part relatively moves in the first direction or the direction opposite to the first direction with respect to the second height control part, the rotation axis is inclined with respect to a plane defined by the second direction and a third direction crossing the first direction and the second direction.

4. The bending apparatus of claim 1, wherein the first height control part relatively moves in a third direction crossing the first direction and the second direction and in a direction opposite to the third direction with respect to the second height control part.

5. The bending apparatus of claim 4, wherein when the first height control part relatively moves in the third direction or the direction opposite to the third direction, the rotation axis is inclined with respect to a plane defined by the first direction and the second direction.

6. The bending apparatus of claim 1, wherein the supporting part extends along an extending direction of the rotation axis, and rotates with respect to the rotation axis by the first rotation part and the second rotation part.

7. The bending apparatus of claim 1, wherein the supporting part comprises:
a fixing part, wherein a first end of the fixing part is attached to the first rotation part, and a second end of the fixing part, which is opposite to the first end thereof, is attached to the second rotation part; and
a moving part which moves in a direction away from the fixing part and in a direction approaching the fixing part.

8. The bending apparatus of claim 1, further comprising:
a stage which relatively moves in a third direction crossing the first direction and the second direction and in a direction opposite to the third direction with respect to the supporting part.

9. The bending apparatus of claim 8, wherein the stage ascends in the first direction and descends in the direction opposite to the first direction.

10. The bending apparatus of claim 1, wherein the first height control part comprises a first lower frame and a first upper frame disposed on the first lower frame, wherein the first upper frame ascends in the first direction and descends in the direction opposite to the first direction with respect to the first lower frame, and
wherein the second height control part comprises a second lower frame and a second upper frame disposed on the second lower frame, wherein the second upper frame ascends in the first direction and descends in the direction opposite to the first direction with respect to the second lower frame.

11. The bending apparatus of claim 10, wherein
the first rotation part is attached to the first upper frame, and
the second rotation part is attached to the second upper frame.

12. The bending apparatus of claim 10, wherein the first upper frame and the second upper frame are moveable independently of each other.

13. A bending method comprising:
preparing a bending apparatus comprising a first height control part which ascend in a first direction and to descend in a direction opposite to the first direction, a second height control part spaced apart from the first height control part in a second direction crossing the first direction, wherein the second height control part ascends in the first direction and descends in the direction opposite to the first direction, a first rotation part attached to the first height control part, wherein the first rotation part rotates with respect to a rotation axis, a second rotation part attached to the second height control part, wherein the second rotation part rotates with respect to the rotation axis, and a supporting part disposed between the first rotation part and the second rotation part, wherein a first end of the supporting part is attached to the first rotation part, and a second end of the supporting part, which is opposite to the first end thereof, is attached to the second rotation part;
disposing a first portion of a bending target on the supporting part; and
bending the bending target by rotating each of the first rotation part and the second rotation part with respect to the rotation axis.

14. The bending method of claim 13, wherein the bending the bending target comprises:
relatively moving the first height control part in the first direction or in the direction opposite to the first direction with respect to the second height control part.

15. The bending method of claim 13, wherein the bending the bending target comprises:
relatively moving the first height control part in a third direction crossing the first direction and the second direction or in a direction opposite to the third direction with respect to the second height control part.

16. The bending method of claim 13, wherein in the bending the bending target,
the supporting part rotates with respect to the rotation axis.

17. The bending method of claim 13, wherein the supporting part comprises a fixing part comprising a first end attached to the first rotation part and a second end attached to the second rotation part, and a moving part which moves in a direction away from the fixing part or in a direction approaching the fixing part, and
wherein the bending the bending target comprises relatively moving the moving part in the direction away from the fixing part or in the direction approaching the fixing part.

18. The bending method of claim 13, wherein the bending apparatus further comprises a stage, and
wherein the bending method further comprises disposing a second portion of the bending target on the stage.

19. The bending method of claim 18, wherein the bending the bending target comprises relatively moving the stage in a third direction crossing the first direction and the second direction or in a direction opposite to the third direction with respect to the supporting part.

20. The bending method of claim 18, wherein the bending the bending target comprises moving the stage in the first direction or in the direction opposite to the first direction.
